(19) United States
(12) Patent Application Publication
(10) Pub. No.: US 2025/0048721 A1
(43) Pub. Date: Feb. 6, 2025

(54) SENSE TRANSISTOR WITH LOWER SPREADING RESISTANCE

(71) Applicant: TEXAS INSTRUMENTS INCORPORATED, Dallas, TX (US)

(72) Inventors: Eung Jung Kim, Allen, TX (US); Thomas Grebs, Fishkill, NY (US); Sunglyong Kim, Allen, TX (US); Sungho Beck, CARROLLTON, TX (US); Wei Fu, Allen, TX (US); Xiaochun Zhao, Allen, TX (US); Arjun Pankaj, Dallas, TX (US)

(21) Appl. No.: 18/228,385

(22) Filed: Jul. 31, 2023

(51) Int. Cl. H01L 29/78; H01L 27/06; H01L 27/092; H01L 29/06; H01L 29/40; H01L 29/66; H01L 29/786

(52) U.S. Cl. CPC H01L 29/7803; H01L 27/0629; H01L 27/0924; H01L 29/0692; H01L 29/402; H01L 29/66712; H01L 29/7813; H01L 29/7869

(57) ABSTRACT

Described examples include an integrated circuit having first and second transistors. The first transistor includes a plurality of trenches extending into a semiconductor substrate and a plurality of source regions, each source region located between a pair of adjacent trenches. A first source terminal is connected to the plurality of source regions. The second transistor includes a central source region between a pair of the trenches and a second source terminal connected to the central source region. The second source terminal is conductively isolated from the first source terminal.

### TECHNICAL FIELD

Disclosed implementations relate generally to power semiconductors, and more particularly to high-capacity transistors.

### BACKGROUND

High-capacity transistors can handle voltages of hundreds of volts and currents greater than amperes. Measurement of the operating current may include a smaller proxy transistor located near the high-current transistor. Accuracy of the value obtained from the proxy transistor is desirable to accurately reflect the current through the high-current transistor.

### SUMMARY

In accordance with various examples, an integrated circuit includes first and second transistors. The first transistor has a plurality of trenches extending into a semiconductor substrate and a plurality of source regions, with each source region located between a pair of adjacent trenches. A first source terminal is connected to the plurality of source regions. The second transistor includes a central source region between a pair of the trenches and a second source terminal connected to the central source region. The second source terminal is conductively isolated from the first source terminal.

Other examples include methods or making and using an integrated circuit including first and second transistors as described above.

### BRIEF DESCRIPTION OF THE DRAWINGS

FIG. 1 is a plan view of an example high-capacity transistor device.

FIG. 2 is a side view of a baseline sense FET.

FIG. 3 is a plan view of a baseline sense FET.

FIG. 4 is a side view of an example sense FET of the disclosure.

FIGS. 5A and 5B are plan views of example sense FETs of the disclosure.

FIGS. 6A through 6K (collectively “FIG. 6”) are side view diagrams of an example process of the disclosure for making an example sense FET.

FIG. 7 is a schematic diagram of a circuit that includes a sense FET according to examples of the disclosure.

FIG. 8 is a flow diagram of a process for using a sense FET for current measurement.

### DETAILED DESCRIPTION

In the drawings, corresponding numerals and symbols generally refer to corresponding parts unless otherwise indicated. The drawings are not necessarily drawn to scale.

In this description, the term “coupled” may include connections made with intervening elements, and additional elements and various connections may exist between any elements that are “coupled.” Also, as used herein, the terms “on” and “over” may include layers or other elements where intervening or additional elements are between an element and the element that it is “on” or “over.”

Various disclosed methods and devices of the present disclosure may be beneficially applied to switching DC-DC converters and other implementations for which accurate sensing of high-current drive transistors is beneficial. While such embodiments may be expected to provide improvements in performance, such as improved operating efficiency of such implementations, no particular result is a requirement unless explicitly recited in a particular claim.

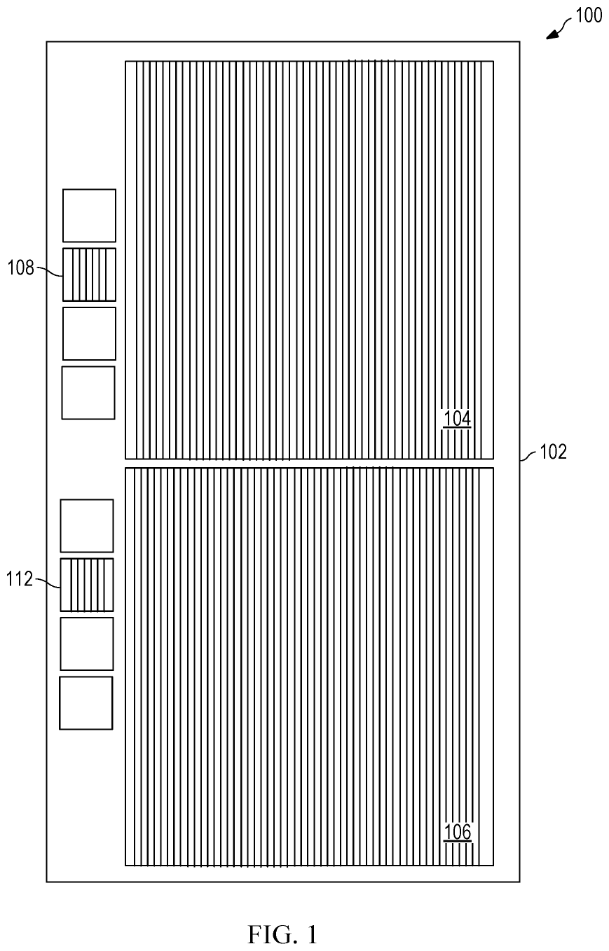

FIG. 1 is a plan view of an example high-current capacity transistor device 100 according to various examples of the disclosure. Substrate 102 includes two high-current or high-power transistors, transistor 104 and transistor 106, which may respectively serve as high-side and low-side transistors of a switching voltage converter circuit such as a buck converter. In this example, substrate 102 serves as the drain for the transistors. Each of the transistors 104, 106 may be a vertical trench field effect transistor (FET) including thousands of vertical FET elements, and thus a commensurate number of trenches. Each vertical FET element may be regarded as a separate active device, and cooperate to function together as a single active device, or transistor. The transistors 104, 106 each have a control terminal, which in the case of the current example is a terminal connection to gate electrodes (not explicitly shown) of the FETs. As further explained hereinbelow, the trenches are filled with a corresponding field plate to dissipate local high electric fields, which facilitates high voltage operation. Gates are formed adjacent to the sidewalls of the trenches, and sources are formed at the top of mesas between neighboring trenches. Among other control circuits, a sense field effect transistor (FET) 108 and a sense FET 112 are included at the periphery of transistors 104 and 106, respectively. The sense FETs 108, 112 may each also each be a vertical trench FET, but include a smaller number of trenches than the transistors 104, 106. In this case, sense FET 108 is used to sense the current in transistor 104 and sense FET 112 is used to sense the current in FET 106. Sense FET 108 and sense FET 112 are formed using the same processing steps as transistor 104 and transistor 106 so that their behavior is nearly the same as these transistors on a smaller scale. The sense FETs 108, 112 may include only a few trenches and thus have a drive current capacity that is a small fraction of that of the transistors 104, 106. The sense FETs 108, 112 may respectively operate in parallel with the transistors 104, 106, with the current through the sense FETs 108, 112 providing a proxy value representative of the current through the transistors 104, 106.

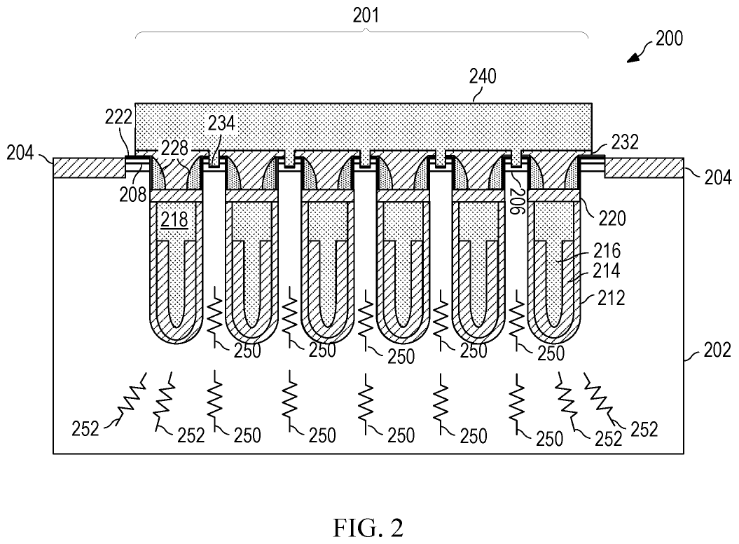

FIG. 2 is a side view of a baseline sense FET 200 that may be used in some baseline implementations. Dielectric isolation structure 204 surrounds sense FET 200 to mitigate the effect of other devices in substrate 202. In this example, sense FET 200 has six trenches 201 that allow for ten parallel transistors between neighboring pairs of the trenches. That is, two transistors are formed on either wall between adjacent trenches. Source contact 240 contacts sources 206. Gates 228 (gate electrodes) control channel regions between the neighboring pairs of trenches 201. Substrate 202 serves as the drain. Layer 208, layer 222 (including layers 220), and plugs 232 electrically separate source contact 240 from gates 228 and from sources 206, except where source contact 240 extends into and connects to sources 206 by way of contacts 234. A wider first field plate 218 and narrower second field plate 216, coupled to a reference potential by a circuit node outside the view of the figure, help avoid locally high field regions in substrate 202. First field plate 218 is separated from substrate 202 by first insulating layer (sidewall liner) 212. Second field plate 216 is separated from substrate 202 by first insulating layer 212 and second insulating layer 214. The thickness of the insulating layers modulates the effect of the field plates along the length of trenches 201. Of importance, resistances 250 affect the specific resistances of the transistors. In addition, on the end transistors, resistances 252 provide parallel resistances for the transistors on the ends of the series of transistors in sense FET 200. The resistances 252 may be collectively referred to as “spreading resistance”.

In the primary transistor, such as transistor 104 (FIG. 1), thousands of trenches may be used. Therefore, the effect of edge resistances like resistances 252 is very small in the primary transistor. However, edge resistances 252 have a much larger effect on sense FET 200. The purpose of sense FET 200 is to represent the behavior of the primary transistor so that, when gates 228 and sources 206 are coupled to the same inputs as the gates and source of the primary transistor, the current through sense FET is as close to proportional to the current through the primary transistor as is possible. This allows for monitoring the current through the primary transistor using the much lower current through sense FET 200. However, the effect of edge resistances 252 negatively impacts the proportionality of the current through sense FET 200.

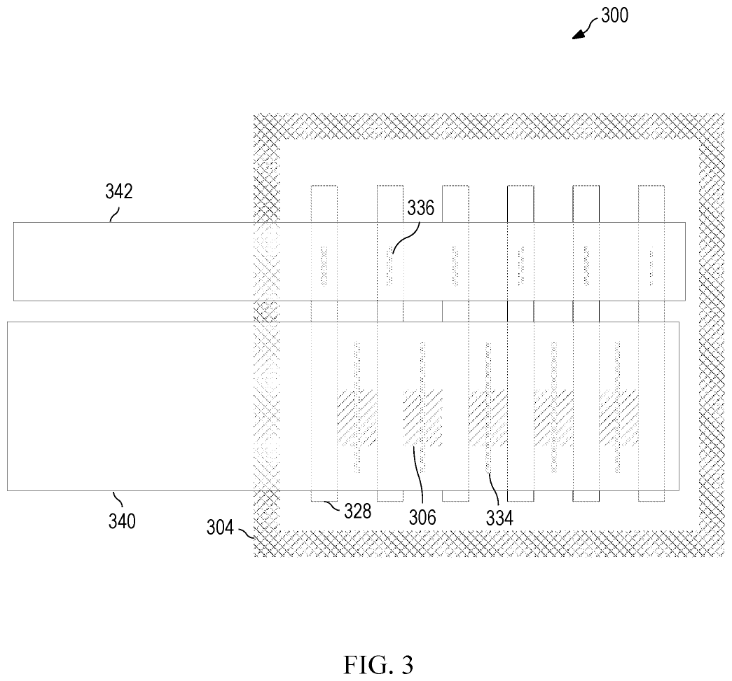

FIG. 3 is a plan view of an example baseline sense FET 300, representative of the baseline sense FET 200. In this example, sense FET 300 is surrounded by dielectric isolation structure 304. Gate terminal 342 contacts gates 328 at contacts 336. In this figure, only one contact is labelled for clarity. Source terminal 340 contacts sources 306 through contacts 334.

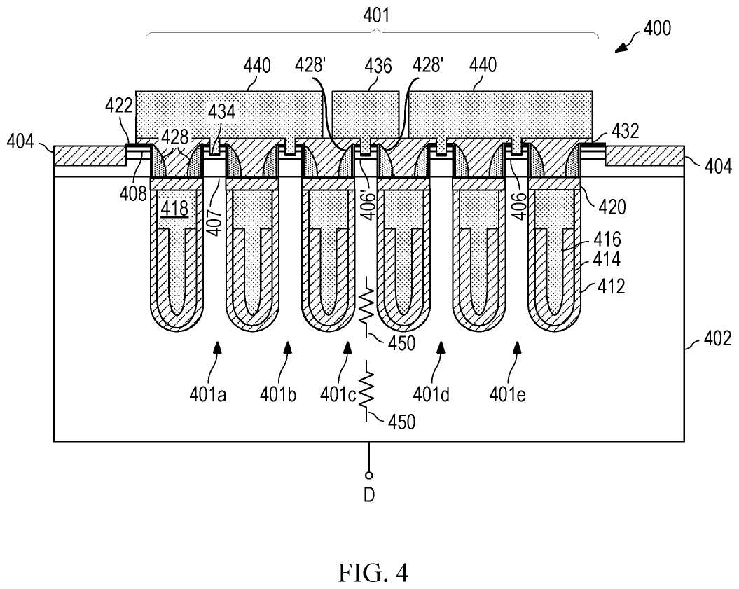

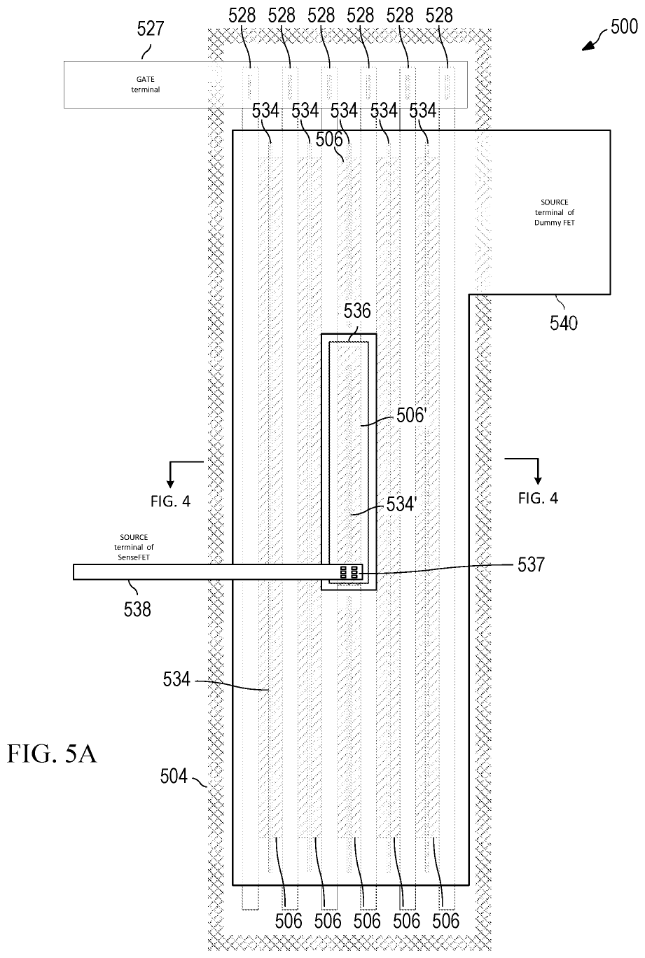

FIG. 4 is a side view of an example sense FET 400 according to the disclosure that is expected to beneficially reduce spreading resistance effects exemplified by baseline sense FET 200. Dielectric isolation structure 404 surrounds sense FET 400 to mitigate the effect of other devices in substrate 402. In some examples the isolation structure 404 is implemented by a shallow trench isolation (STI) structure or deep-trench isolation structure. In some other examples the isolation structure 404 may be omitted. In this example, sense FET 400 has a linear array 401 of active devices, e.g. parallel vertical LDMOS transistors formed on adjacent pairs of walls between parallel trenches. That is, a vertical transistor is formed at both walls between the trenches. There are five pairs of vertical LDMOS transistors in the illustrated example, 401a . . . 401e. Transistor pair 401c is a sensing active device, and transistor pairs 401a, 401b, 401d and 401e are dummy active devices. In this context, “dummy active device” means that such devices may be operable to conduct a current consistent with the transistor design, but such devices do not contribute directly to the current sensing function of the sense FET 400.

Source contact 440 contacts sources 406 and source contact 436 contacts source 406′. Thus the source contact 440 may function as a current handling terminal with respect to the transistor pairs (dummy active devices) 401a, 401b, 401d and 401e, and the source contact 436 may function as a current handling terminal with respect to the transistor pair 401c. Body regions 407 extend from sources 406, 406′ to approximately the bottom of gates 428. Gates 428 control channels within the body regions 407. In this example, substrate 402 serves the drain for sense FET 400 and the drain for a transistor such as the transistor 104 so that the drains of both transistors may be connected to a same voltage node, e.g. the substrate backside, which serves as current handling terminal for the transistor 104, the transistor pairs 401a, 401b, 401d and 401e, and the transistor pair 401c. Layer 408, layer 422 (including layers 420), and dielectric plugs 432 electrically separate source contact 440 from gates 428 and from sources 406, and contact 436 from gates 428′ and from source 406′, except where source contact 440 and source contact 436 connect to sources 406, 406′ by way of contacts 434. Wider first field plate 418 and narrower second field plate 416 are coupled to a reference potential outside the view of the figure and help avoid local high field regions in substrate 402. First field plate 418 is separated from substrate 402 by first insulating layer (sidewall dielectric) 412. Second field plate 416 is separated from substrate 402 by first insulating layer 412 and second insulating layer 414. The thickness of the insulating layers modulates the effect of the field plates along the length of trenches in the linear array 401. Of importance, separate source contact 436 allows for a separate connection to the centermost transistor pair 401c and thus a subset of the vertical LDMOS transistors. Source contact 440 can then be connected to the source terminal of the primary transistor so that the transistors on opposite ends of the linear array of trenches that are subject to edge resistances (spreading resistance) 252 (FIG. 2) are not used to measure current, thus increasing the accuracy of the current measurement. In this example, source contact 440 contacts the same number of transistors on opposite sides of the centermost transistors, though other examples may not. Resistances 450 represent the drain drift resistance experiences by the transistor pair 401c, which is substantially direct, e.g. low spreading resistance, between the source 406′ and the drain D as a result of shielding by the transistor pairs 401a, 401b, 401d and 401e. Without the dummy pattern surrounding transistor pair 401c, which operates as the sense FET, the sense FET would otherwise be affected by the spreading resistance effect, and its drain-side resistance would be reduced, causing a systematic error in current sensing.

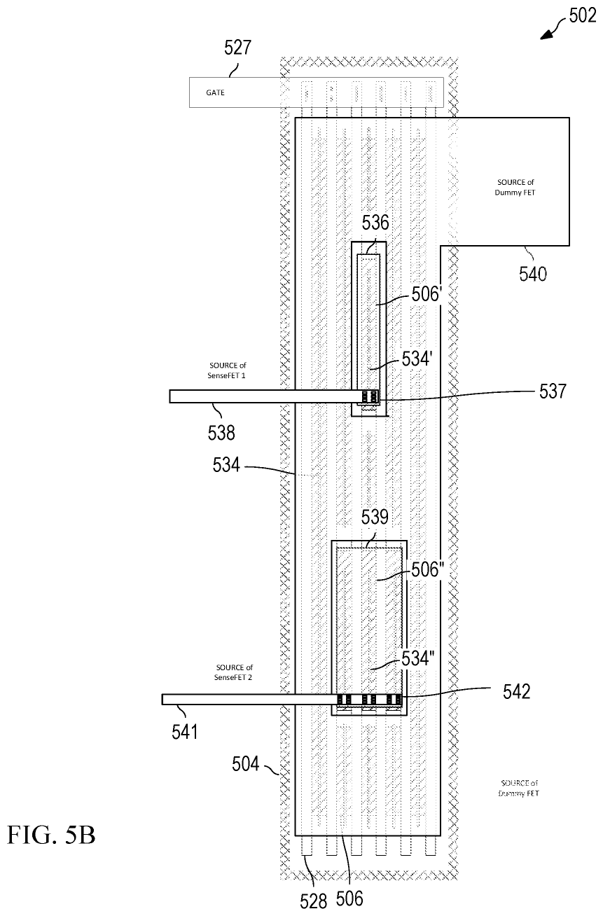

FIG. 5A is a plan view of example sense FET 500 exemplified by the sense FET 400 (FIG. 4). Optional dielectric isolation structure 504 surrounds sense FET 500. Gate terminal 527 is connected to all of the gates 528, and thus all of gates 528 are connected to the same gate terminal. Source terminal 536 is coupled to source 506′ in the central most inter-trench region by a contact 534′. The source 506′ may be disconnected from the sources 506 colinear with the source 506′ A connection to source terminal 536′ is provided by lead 538, which is in a higher level of metallization, through vias 537. Contacts 534 connect dummy source terminal 540 to sources 506, which are all of the sources not coupled to source terminal 536. As before, for clarity only one contact 534 is shown for each source 506. The transistor elements connected to the dummy source terminal 540 may generally operate as, and may be considered, a single transistor. In various examples, and as illustrated, the dummy source terminal 540 completely surrounds the source terminal 536. In some examples, and as illustrated, the source terminal 536 is centrally located within the dummy source terminal 540, such that the dummy source terminal 540 extends about a same distance horizontally to the left and right of the source terminal 536 as viewed in the figure, and extends about a same distance vertically above and below the source terminal 536 as viewed in the figure. Source terminal 536 is coupled to sense circuitry (not shown) to measure the sense FET current. Dummy source terminal 540 may be coupled to a dummy load (not shown) that is similar to the load provided by the sense circuitry, or may be connected to the source terminal of the primary transistor being monitored. Thus, the current sensed by the sense circuitry is only from the central-most inter-trench transistors that are not affected by the spreading resistance, e.g. as illustrated by resistances 252 (FIG. 2). This provides a sense FET 500 that is more accurately proportional to the transistor of interest, e.g. the transistor 104 (FIG. 1).

FIG. 5B is a plan view of another sense FET 502. Sense FET 502 is also exemplified by sense FET 400 (FIG. 4). Optional dielectric isolation structure 504 surrounds sense FET 502. Similar to the sense FET 500, source terminal 536, now referred to as first source terminal 536, is only coupled to the source 506′ in the central most inter-trench region by a contact 534′. Differently from the sense FET 500, second source terminal 539 is coupled to three source regions 506″ by contacts 534″, the central most inter-trench region and the two adjacent inter-trench regions. Lead 538 and vias 537 provide a connection to source terminal 536. Lead 541 and vias 542 provide a connection to source terminal 539. The transistor elements connected to the source terminal 539 may generally operate as, and may be considered, a single transistor. As with FIG. 5A, only one contact 534, 534′, 534″ is labeled for clarity. Dummy source terminal 540 is coupled to all of sources 506 that are not coupled to source terminal 536 or source terminal 539. Of note, the source 506′ that is coupled to first source terminal 536 and sources 506″ coupled to second source terminal 539 are separated from sources 506 that are coupled to dummy source terminal 540. First source terminal 536 and second source terminal 539 may be coupled to sense circuitry (not shown) to measure the sense FET current. Source terminal 540 may be coupled to a dummy load (not shown) that is similar to the load provided by the sense circuitry or to the source terminal of the primary transistor being monitored. Thus, the current sensed by the sense circuitry from first source terminal 536 is only from the central-most inter-trench transistor that is not affected significantly, if at all, by spreading resistance effects. In contrast, the current sensed by the sense circuitry for second source terminal 539 is only from the three center most source regions 506. Thus, sense FET 502 essentially includes two sense transistors with slightly different characteristics that can be mathematically combined or compared by control circuitry (not shown). It can be experimentally determined what mathematical combination of the two sense transistors provides the most accurate proportionality with the primary transistor, e.g. transistor 104 (FIG. 1). This may provide a sense FET 502 that is more accurately proportional to the primary FET 104 (FIG. 1).

The examples of FIGS. 5A and 5B (collectively “FIG. 5”) are only two examples among many in which the sense FET can be configured. For example, the active sense element can be bordered by from one to 100 dummy sources to minimize the spreading resistance where 4-5 dummy sources may be optimal depending on resistance fringing and area consumed by overall layout. The configurations of FIG. 5 use fewer dummy sources and only one or three active sources for clarity of the figures.

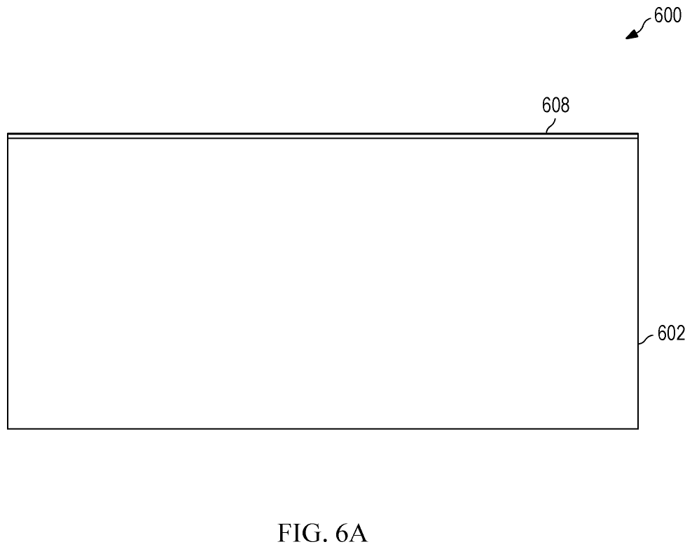

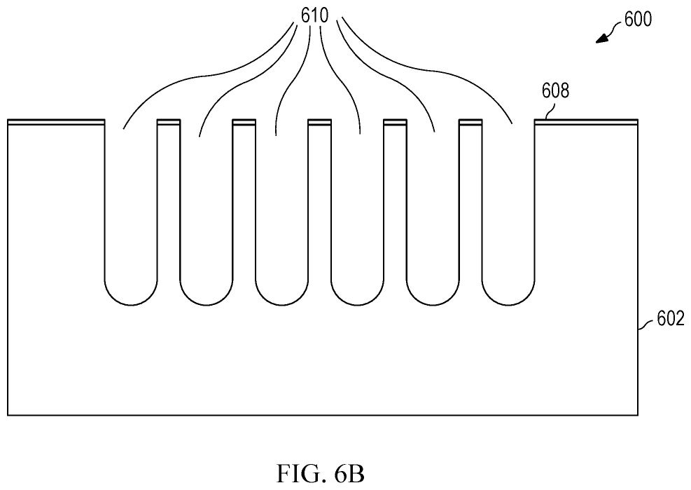

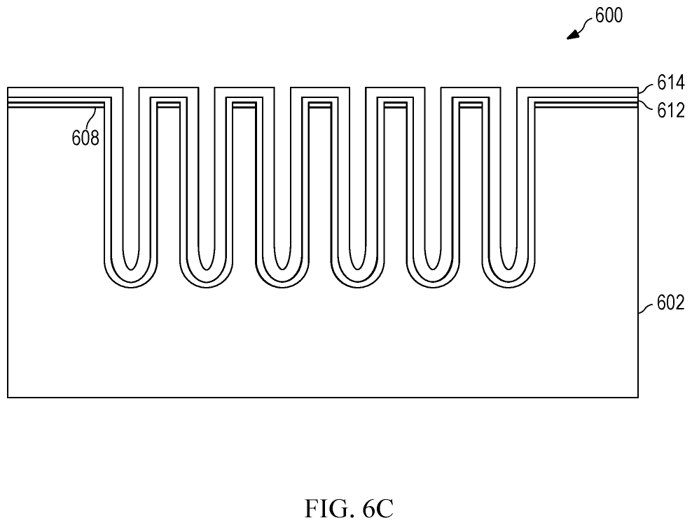

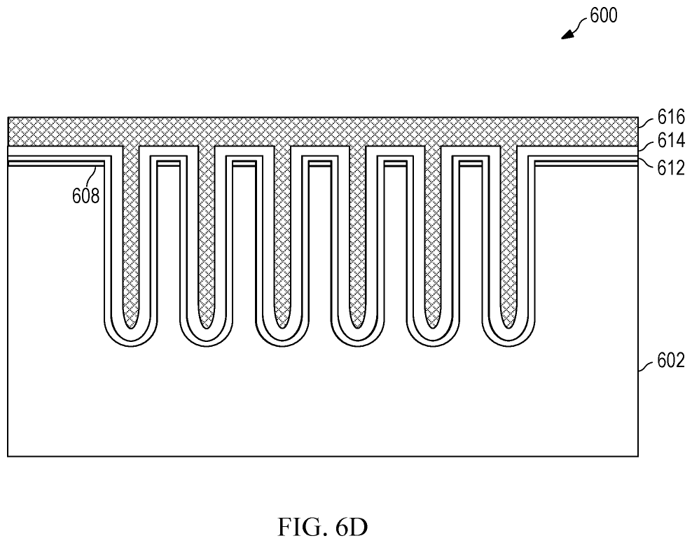

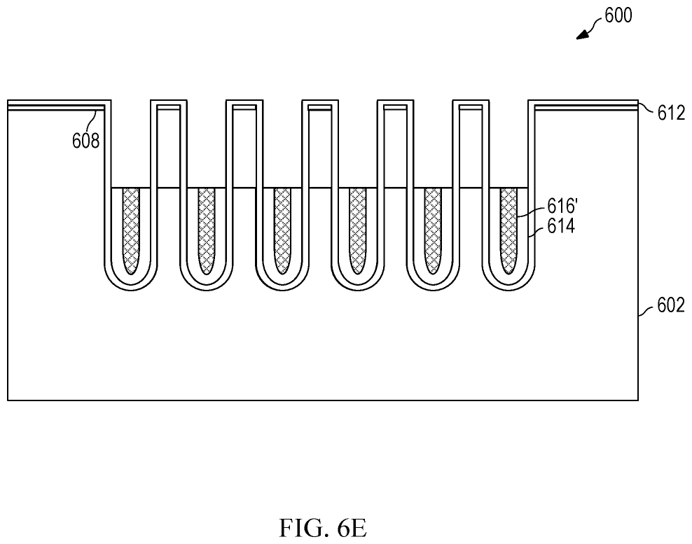

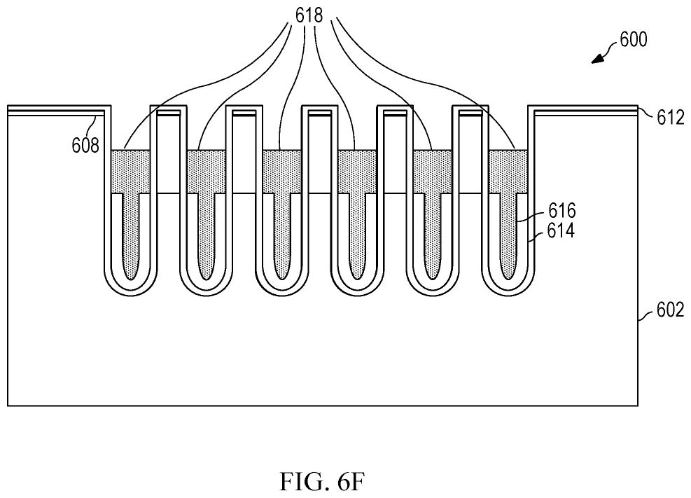

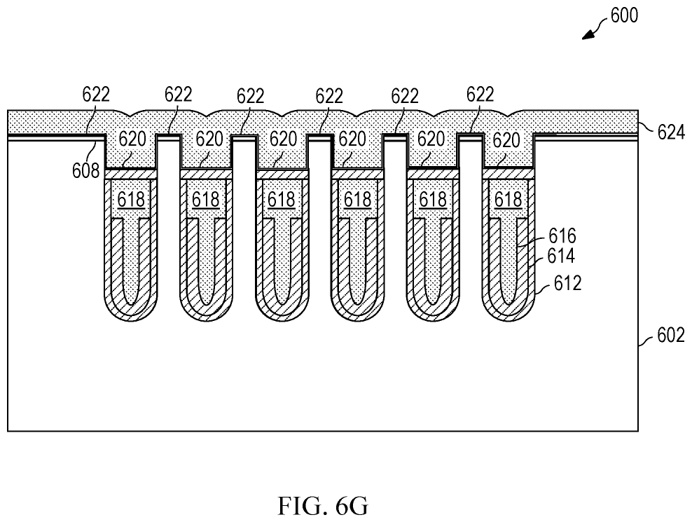

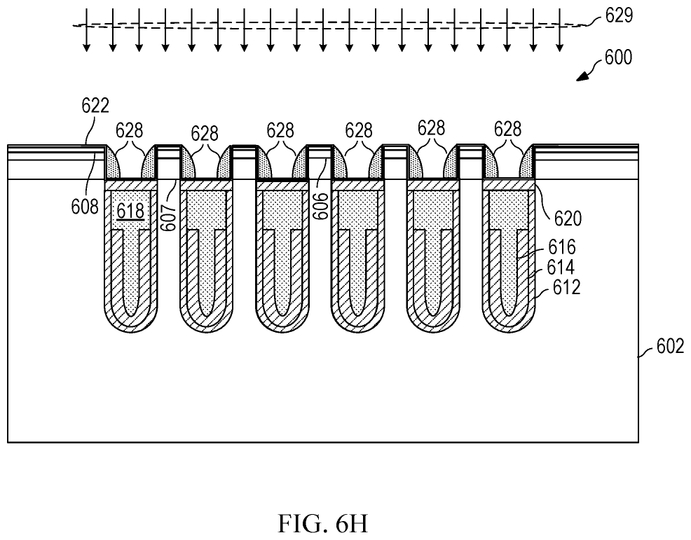

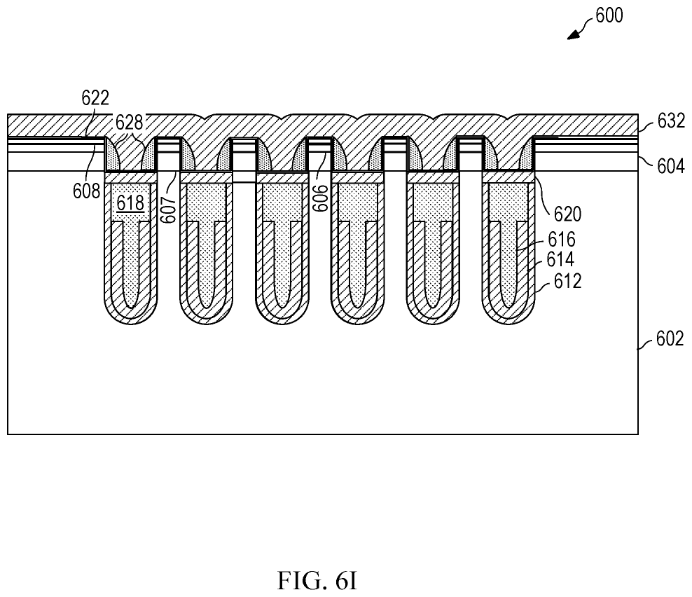

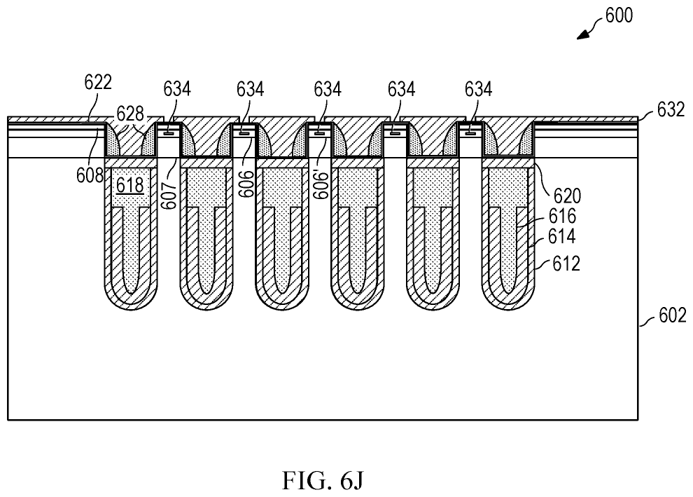

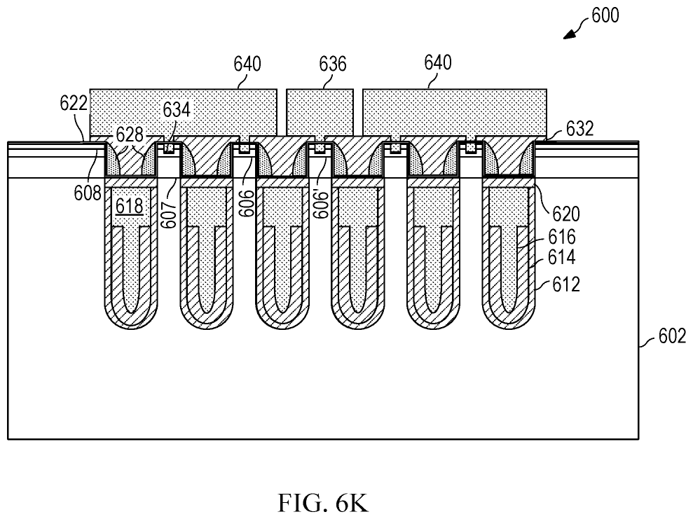

FIGS. 6A through 6K (collectively “FIG. 6”) are side view diagrams of an example process for making an example sense FET 600, representative of the sense FETs 400, 500, 502 and other examples consistent with the disclosure. Of note, this process applies equally to making the trench transistors of the primary FET 104 (FIG. 1). Making the sense FET and main FET using the same process increases the probability that the current through sense FET 600 is accurately proportional to the current through primary FET 104 across the range of gate inputs, thus providing an accurate sensing of the current through primary FET 104 (FIG. 1).

FIG. 6A shows semiconductor substrate 602 on which silicon dioxide layer 608 is formed using thermal oxidation in steam at a temperature of 900° C., for example, to a thickness of approximately 10 nm (with a range of 5 nm to 20 nm). Not shown, an optional isolation structure may be provided in the substrate 602 as exemplified by the isolation structure 404 (FIG. 4.).

FIG. 6B shows the sense FET 600 after forming trenches 610. The trenches 610 may be formed using a patterned mask to etch silicon dioxide layer 608. This patterned silicon dioxide layer 608 may be used as a mask (e.g. a hardmask) for etching trenches 610 into substrate 602. In an example, reactive ion etching is used to form trenches 610. Thus, source region 606 is divided into several source regions, each between an adjacent pair of trenches. FIG. 6C shows the sense FET 600 after forming thermal silicon dioxide layer 612, e.g. by steam oxidation at a temperature of 900° C. to a thickness of 100 nm (with a range of 50 nm to 150 nm). While thermal silicon dioxide layer 612 is shown as being uniform, in some cases, the thickness of thermal silicon dioxide layer 612 will vary. Silicon dioxide layer 614 has been formed on thermal silicon dioxide layer 612, e.g. using chemical vapor deposition (CVD), to a thickness of 50 nm (with a range of 30 nm to 80 nm).

In FIG. 6D the trenches 610 have been filled with photoresist layer 616, which extends above the trenches. In examples, photoresist layer 616 is spun-on and provides a planar top surface. Photoresist layer 616 is then exposed to light so that the top portion photoresist layer 616 is developed and then removed. A remaining portion of photoresist layer 616′ is shown in FIG. 6E. The remaining photoresist layer 616′ can occupy 20-80% of the depth of the trenches, depending on the time of photoresist exposure and the type of photoresist used. The height of the remaining photoresist layer 616′ is selected to provide a desired height of the narrower field plate that will subsequently be formed in the trench. The exposed portions of silicon dioxide layer 614 are removed using a wet etch that is selective to CVD deposited oxides versus thermal oxides. An example of such an etch is a buffered hydrofluoric acid (HF) solution that is 10 parts 40% ammonium fluoride and one part 49% hydrofluoric acid, which is approximately twice as selective to CVD oxide relative to thermal oxide. Afterwards the remaining photoresist layer 616 is removed by solvent and/or ashing.

As shown in FIG. 6F, a polysilicon layer has been deposited, planarized, and etched back to form field plates 618. The field plates 618 may be in-situ doped, e.g. with boron, to provide a desired conductivity. FIG. 6G shows the sense FET 600 after silicon dioxide layer 620 and gate oxide layers 622 have been formed, e.g. by thermal oxidation. The gate oxide layers 622 may have a thickness of 5 nm (with a range of 3.5 nm to 10 nm). Silicon dioxide layers 620 are thicker than gate oxide layers 622 because of the more rapid oxidation of doped polysilicon in field plates 618. Polysilicon layer 624 is then deposited by CVD to a thickness of 400 to 600 nm. Polysilicon layer 624 may be doped to a dopant density of 1 to 5×10¹⁸ atoms/cm³ by in-situ doping or subsequent ion implantation. This dopant provides for high conductivity of polysilicon layer 624.

As shown in FIG. 6H, polysilicon layer 624 is subjected to anisotropic reactive ion etching (RIE) so that all of polysilicon layer 624 is removed except for sidewall gates 628 (gate electrodes). A dual implantation 629 forms body region 607 and source regions 606. Source regions 606 may be formed by an ion implantation of phosphorous ions with a density of 1×10¹⁵ atoms/cm² (with a range of 0.5×10¹⁵ atoms/cm² to 2×10¹⁵ atoms/cm²) and an energy of 35 keV (with a range of 30 keV to 40 keV). Body regions 607 may be formed by ion implantation of boron atoms 5×10¹³ atoms/cm² (with a range of 1×10¹³ atoms/cm² to 1×10¹⁴ atoms/cm²) and an energy of 60 keV (with a range of 55 keV to 65 keV). As shown in FIG. 6I, silicon dioxide layer 632 may be deposited using CVD. Silicon dioxide layer 632 is then planarized and etched back as shown in FIG. 6J, so that the portion of silicon dioxide layer 632 above silicon dioxide layer 608 is approximately 200 nm thick. Using a patterned photoresist layer (not shown), openings in the inter-trench regions to silicon dioxide layer 608 are etched. Using the patterned silicon dioxide layer 632, source contacts 634 are implanted, e.g. using ion implantation of phosphorus ions with a density of 1×10¹⁶ atoms/cm² (with a range of 0.5×10¹⁶ atoms/cm² to 2×10¹⁶ atoms/cm²) and an energy of 20 keV (with a range of 15 keV to 25 keV). Using patterned silicon dioxide layer 632 as a mask, an opening to source contacts 634 is etched as shown in FIG. 6K. A layer of polysilicon is then deposited and patterned to form source leads 640 and 636.

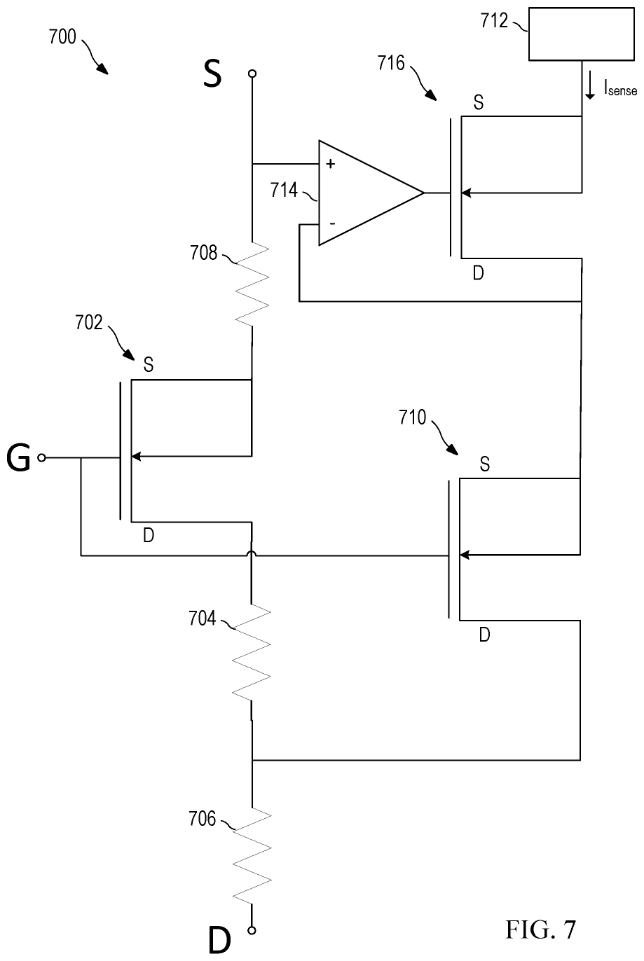

FIG. 7 is a schematic diagram of an example circuit 700 that may use a sense FET according to examples of the disclosure. Overall, circuit 700 provides a high current-capacity transistor having terminals S (source), G (gate), and D (drain). The gate of transistor 702 is connected to terminal G, the drain of transistor 702 is connected to terminal D through resistance 704 and resistance 706, and the source of transistor 702 is connected to terminal S through resistance 708. The transistor 702 is exemplified by the transistor 104 (FIG. 1). The resistances 704, 706, 708 may be provided by the resistance of a semiconductor on which the circuit 700 is implemented, as exemplified by the substrate 402 (FIG. 4), or by diffusion or poly resistors formed in or over the substrate. A sense FET 710 has a gate connected to terminal G and a drain connected to a node between the resistances 704, 706. The sense FET 710 may be exemplified by the sense FETs 108, 400, 500 and 502.

To provide an accurate analog of the current I through transistor 702, sense FET 710 needs the same source voltage as applied at the terminal S. However, it is desirable to keep the current through sense FET 710 separate so that it can be accurately sensed by current sensor 712. To achieve this, circuit 700 includes op amp 714 with the positive input coupled to terminal S. The high input impedance of op amp 714 means that op amp 714 has very little effect on the operation of transistor 702. A negative feedback loop is provided through transistor 716 to the negative input of op amp 714. Any deviation from the voltage on terminal S at the source of sense FET 710 causes the output voltage of op amp 714 to adjust the voltage on the gate of transistor 716 to bring the voltage on the source of sense FET 710 back into sync with the voltage on terminal S. The resulting current Iₛₑₙₛₑ is then representative of the current through the transistor 702.

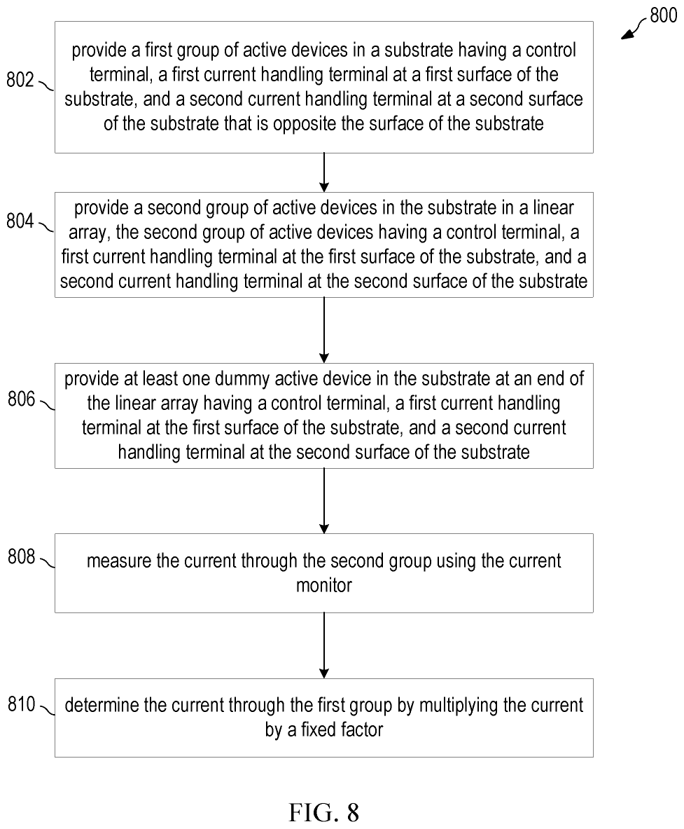

FIG. 8 is a flow diagram of a process 800 for using the sense FET, e.g. sense FET 400 (FIG. 4), sense FET 500 or sense FET 502 (FIG. 5) for current measurement of a primary transistor such as transistor 104 (FIG. 1). In step 802 a first group of active devices having a first control terminal is provided in or over a substrate, a first current handling terminal at a first surface of the substrate, and a second current handling terminal at a second surface of the substrate that is opposite the first surface of the substrate. Step 804 is providing a second group of active devices in or over the substrate in a linear array, the second group of active devices having a second control terminal conductively coupled to the first control terminal, a third current handling terminal at the first surface of the substrate, and a fourth current handling terminal at the second surface of the substrate conductively coupled to the second current handling terminal.

Step 806 is providing at least one dummy active device in the substrate at an end of the linear array having a third control terminal conductively coupled to the first control terminal, a fifth current handling terminal at the first surface of the substrate, and a sixth current handling terminal at the second surface of the substrate conductively coupled to the second current handling terminal. Step 808 is providing a current monitor coupled to the third current handling terminal and measuring current through the second group using the current monitor. Step 810 is determining the current through the first group by multiplying the current by a fixed factor.

Modifications are possible in the described examples, and other examples are possible, within the scope of the claims.

What is claimed is:

1. An integrated circuit, comprising:
a first transistor including:
a plurality of trenches extending into a semiconductor substrate;
a plurality of source regions, each source region between a pair of adjacent trenches; and
a first source terminal connected to the plurality of source regions; and
a second transistor including:
a central source region between a pair of the trenches; and
a second source terminal connected to the central source region and conductively isolated from the first source terminal.

2. The integrated circuit of claim 1, wherein the central source region is colinear with one of the plurality of source regions.

3. The integrated circuit of claim 1, wherein the first source terminal completely surrounds the second source terminal.

4. The integrated circuit of claim 1, wherein the first transistor includes a plurality of gate electrodes, each gate electrode in a corresponding one of the plurality of trenches, and the second transistor includes a pair of gate electrodes, each of the pair of gate electrodes in a corresponding one of the pair of adjacent trenches, the plurality of gate electrodes and the pair of gate electrodes connected to a same gate terminal.

5. The integrated circuit of claim 1, wherein a drain of the first transistor and a drain of the second transistor are connected in parallel to a same voltage node.

6. The integrated circuit of claim 1, wherein the second transistor includes a plurality of the trenches.

7. The integrated circuit of claim 1, wherein the central source region is a first central source region, and further comprising:
a third transistor including:
a second central source region between a pair of the trenches; and
a third source terminal connected to the second central source region and conductively isolated from the first source terminal and the second source terminal.

8. The integrated circuit of claim 7, wherein the first source terminal completely surrounds the second source terminal and completely surrounds the third source terminal.

9. The integrated circuit of claim 1, wherein the central source region is between a first subset of the trenches and a second subset of the trenches, the first and second subset having a same number of trenches.

10. The integrated circuit of claim 1, wherein the first transistor shields the second transistor from spreading resistance.

11. A method of forming an integrated circuit, comprising:
forming a first transistor in or over a semiconductor substrate, including:
forming a plurality of trenches extending into the semiconductor substrate;
forming a plurality of source regions, each source region between a pair of adjacent trenches; and
connecting a first source terminal to the plurality of source regions; and
forming a second transistor in or over the semiconductor substrate, including:
forming a central source region between a pair of the trenches of the first transistor; and
connecting a second source terminal to the central source region and conductively isolated from the first source terminal.

12. The method of claim 11, wherein the central source region is colinear with one of the plurality of source regions.

13. The method of claim 11, wherein a first source terminal completely surrounds the second source terminal.

14. The method of claim 11, wherein the first transistor includes a plurality of gate electrodes, each gate electrode in a corresponding one of the plurality of trenches, and the second transistor includes a pair of gate electrodes, each of the pair of gate electrodes in a corresponding one of the pair of adjacent trenches, the plurality of gate electrodes and the pair of gate electrodes connected to a same gate terminal.

15. The method of claim 11, wherein a drain of the first transistor and a drain of the second transistor are connected in parallel to a same voltage node.

16. The method of claim 11, wherein the second transistor includes a plurality of the trenches.

17. The method of claim 11, wherein the central source region is a first central source region, and further comprising forming a third transistor including:
forming a second central source region between a pair of the trenches; and
forming a third source terminal connected to the second central source region and conductively isolated from the first source terminal and the second source terminal.

18. The method of claim 17, wherein the first source terminal completely surrounds the second source terminal and completely surrounds the third source terminal.

19. The method of claim 11, wherein the central source region is between a first subset of the trenches and a second subset of the trenches, the first and second subset having a same number of trenches.

20. The method of claim 11, further comprising a connecting a current monitor configured to sense a current through the second transistor.
